(19) United States
(12) Patent Application Publication
(10) Pub. No.: US 2009/0116189 A1
(43) Pub. Date: May 7, 2009

(54) Cooling System for a Computer Power Supply Unit

(75) Inventors: Yung-Yu Chang, Tainan-Hsien (TW); Cheng-Pin Lin, Tainan City (TW); Yu-Feng Tsai, Tainan Hsien (TW)

Correspondence Address: MCDERMOTT WILL & EMERY LLP, 2049 CENTURY PARK EAST, 38th Floor, LOS ANGELES, CA, 90067-3208, US

(73) Assignee: Compucase Enterprise Co., Ltd. (Taiwan)

(21) Appl. No.: 11/935,978

(22) Filed: Nov. 6, 2007

(51) Int. Cl. H05K 7/20; G05D 23/00

(52) U.S. Cl. 361/695; 700/300

(57) ABSTRACT

A cooling system for a computer power supply unit includes: a housing; a plurality of cooling fans; a temperature controller; at least one temperature sensor coupled electrically to the temperature controller; and a plurality of fan-driving circuits coupled electrically and respectively to the cooling fans and controlled by the temperature controller for activating and deactivating the cooling fans, respectively. The temperature controller is configured with different temperature settings, each corresponding to a number of the cooling fans, and controls the fan-driving circuits to activate a number of the cooling fans according to the temperature setting corresponding to a temperature detected by the temperature sensor.

### BACKGROUND OF THE INVENTION

1. Field of the Invention

The invention relates to a cooling system for a computer power supply unit, more particularly to a cooling system including a plurality of fans controlled by a controller.

2. Description of the Related Art

In the past, a conventional cooling system for a computer power supply unit usually includes a cooling fan that is activated when the power supply unit is turned on for heat dissipation. As the complexity and processing speed of electronic components in the power supply unit have considerably increased, a large amount of heat is generated inside the power supply unit. In order to remove the large amount of heat, there has been proposed a cooling system that includes a temperature controller, a temperature sensor and two or more cooling fans for cooling the power supply unit. Each cooling fan corresponds to a number of the electronic components. However, since the cooling fans are activated simultaneously by the controller whenever the temperature sensor detects that a temperature that is higher than a temperature threshold in the temperature controller and are deactivated simultaneously by the controller whenever the temperature sensor detects a temperature that is lower than a temperature threshold in the temperature controller, i.e., the cooling fans are driven by one driving circuit, waste of consumed power is incurred when only one cooling fan is required for cooling the corresponding electronic components. In addition, when one of the cooling fans malfunctions, others are affected and cannot be used until the malfunctioning cooling fan is repaired.

### SUMMARY OF THE INVENTION

Therefore, the object of the present invention is to provide a cooling system that can overcome the drawbacks associated with the prior art.

According to one aspect of the present invention, there is provided a cooling system that is adapted for a computer power supply unit and that comprises: a housing; a plurality of cooling fans mounted in the housing; a temperature controller mounted in the housing; at least one temperature sensor mounted in the housing and coupled electrically to the temperature controller; and a plurality of fan-driving circuits coupled electrically and respectively to the cooling fans and controlled by the temperature controller for activating and deactivating the cooling fans, respectively. The temperature controller is configured with different temperature settings, each corresponding to a number of the cooling fans, and controls the fan-driving circuits to activate a number of the cooling fans according to the temperature setting corresponding to a temperature detected by the at least one temperature sensor.

According to another aspect of the present invention, there is provided a cooling system that is adapted for a computer power supply unit and that comprises: a housing; a plurality of cooling fans mounted in the housing; a temperature controller mounted in the housing; a plurality of temperature sensors mounted in the housing and coupled electrically to the temperature controller; and a plurality of fan-driving circuits coupled electrically and respectively to the cooling fans and controlled by the temperature controller for activating and deactivating the cooling fans, respectively. The temperature controller controls each of the fan-driving circuits to activate the respective one of the cooling fans according to a temperature detected by a corresponding one of the temperature sensors.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of the first preferred embodiment of a cooling system for a computer power supply unit according to the present invention;

FIG. 2 is an exploded perspective view of the first preferred embodiment;

FIG. 3 is a partly sectional view of the first preferred embodiment;

FIG. 4 is a system structure block diagram of the first preferred embodiment;

FIG. 5 is an exploded perspective view of the second preferred embodiment of the cooling system according to the present invention; and

FIG. 6 is a system structure block diagram of the second preferred embodiment.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

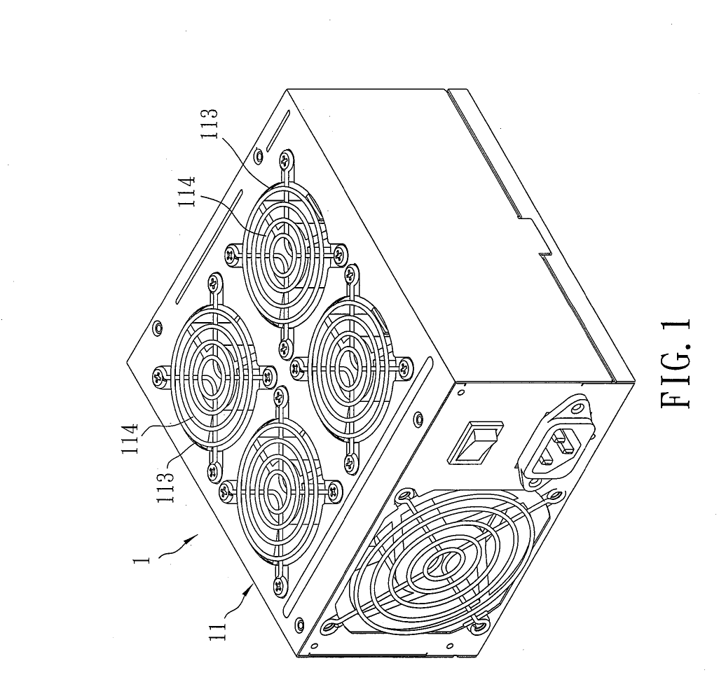

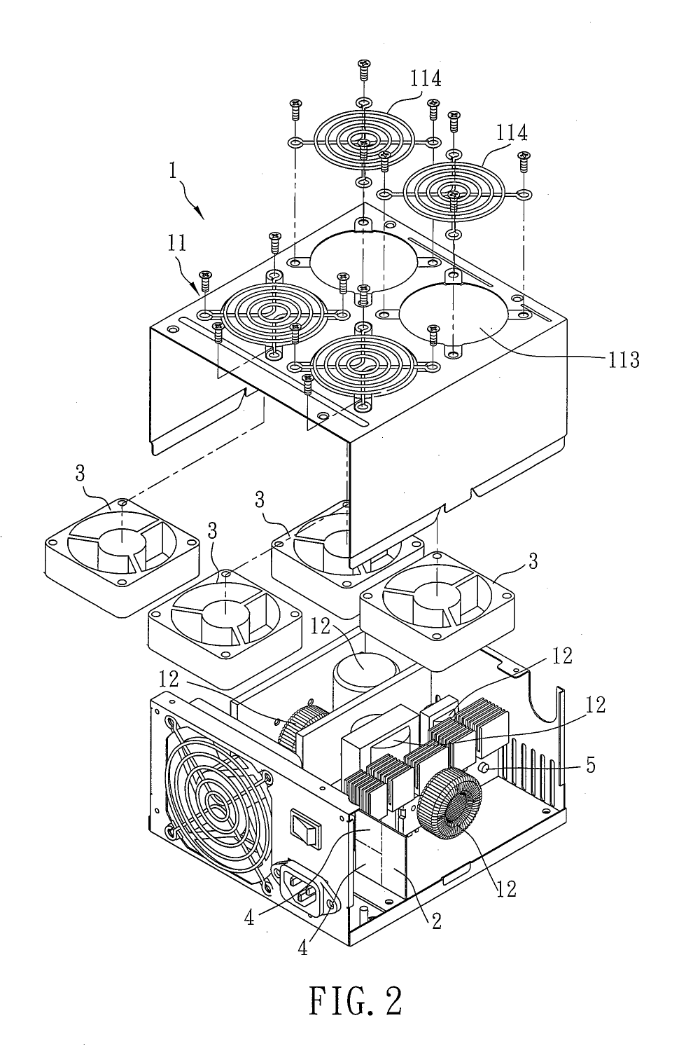

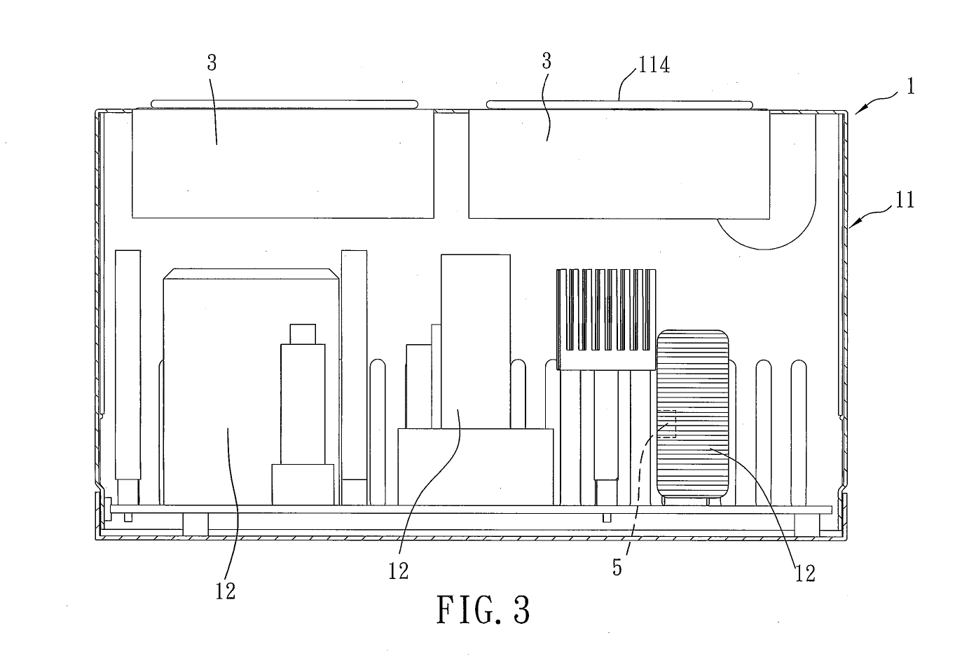

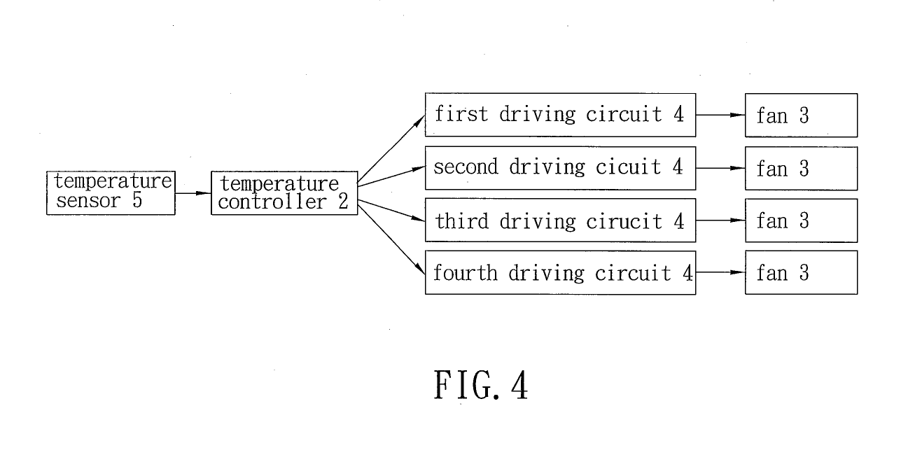

Referring to FIGS. 1 to 4, the first preferred embodiment of a cooling system according to the present invention is shown to be adapted for a computer power supply unit 1. The cooling system includes: a housing 11; a plurality of cooling fans 3 mounted in the housing 11; a temperature controller 2 mounted in the housing 11; one temperature sensor 5 mounted in the housing 11 and coupled electrically to the temperature controller 2; and a plurality of fan-driving circuits 4 coupled electrically and respectively to the cooling fans 3 and controlled by the temperature controller 2 for activating and deactivating the cooling fans 3, respectively. The temperature controller 2 is configured with different temperature settings, each corresponding to a number of the cooling fans 3, and controls the fan-driving circuits 4 to activate a number of the cooling fans 3 according to the temperature setting corresponding to a temperature detected by the temperature sensor 5.

The housing 11 is formed with a plurality of mounting holes 113, each of which is used for mounting a respective one of the cooling fans 3. The housing 11 includes a plurality of protective screens 114, each of which is mounted on a periphery of a respective one of the mounting holes 113.

The temperature sensor 5 is disposed adjacent to one of the electronic components 12 for detecting temperature therearound. It should be noted herein that the number of the temperature sensor 5 is not limited to one and can be increased in number according to the actual requirements.

In operation, heat is generated by the electronic components 12, and the temperature around said one of the electronic components 12 is detected by the temperature sensor 5 and is sent to the temperature controller 2. When the detected temperature reaches a minimum temperature setting, the temperature controller 2 activates a selected one of the fan-driving circuits 4, which, in turn, results in activation of a corresponding one of the cooling fans 3 (the rest of the cooling fans 3 remain idle). When the detected temperature reaches the next higher temperature setting, a larger number of the fan-driving circuits 4 are activated, which, in turn, results in activation of a larger number of the cooling fans 3 than that activated when the minimum temperature setting is reached. When the detected temperature reaches the maximum temperature setting, the fan-driving circuits 4 are all activated by the temperature controller 2 to activate all of the cooling fans 3

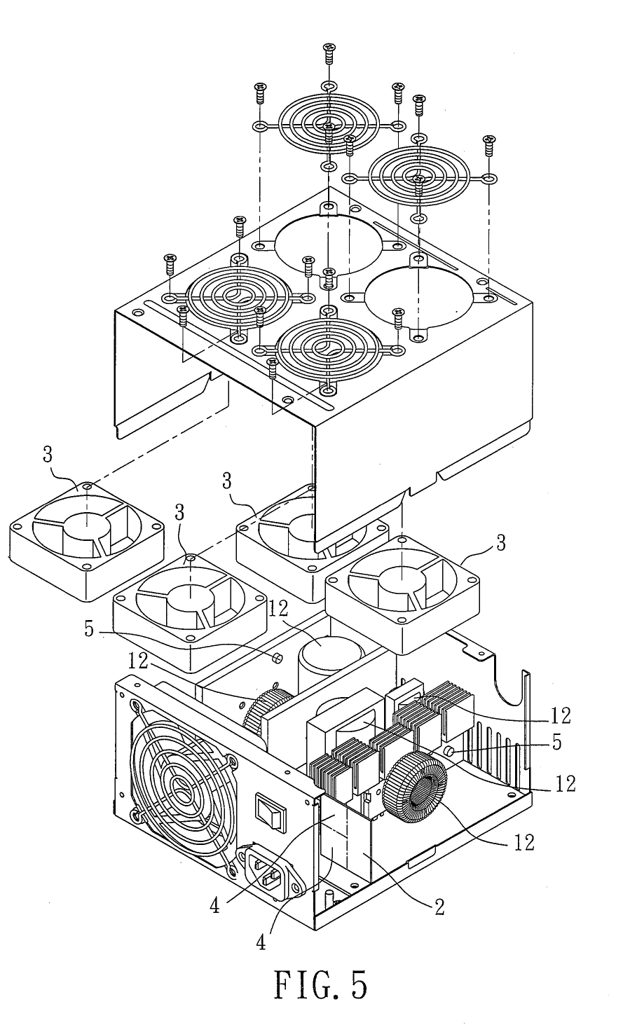

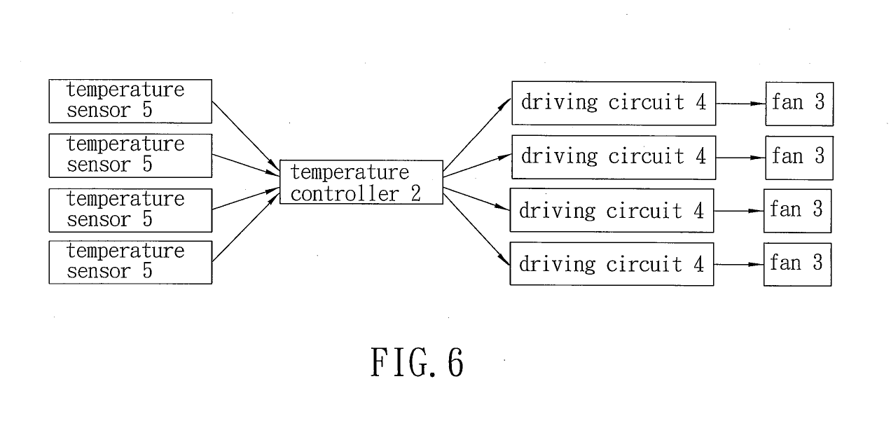

FIGS. 5 and 6 illustrate the second preferred embodiment of a cooling system according to this invention. The second preferred embodiment differs from the first preferred embodiment in that the cooling system of this embodiment includes a plurality of temperature sensors 5 associated with the cooling fans 3, respectively, and that the temperature controller 3 controls each of the fan-driving circuits 4 to activate the respective one of the cooling fans 3 according to a temperature detected by a corresponding one of the temperature sensors 5.

By controlling independently the cooling fans 3 through the temperature settings in the temperature controller 2 or through the temperature sensors 5 of the cooling system of this invention, the aforesaid drawbacks associated with the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A cooling system for a computer power supply unit, comprising:
a housing;
a plurality of cooling fans mounted in said housing;
a temperature controller mounted in said housing;
at least one temperature sensor mounted in said housing and coupled electrically to said temperature controller; and
a plurality of fan-driving circuits coupled electrically and respectively to said cooling fans and controlled by said temperature controller for activating and deactivating said cooling fans, respectively;
wherein said temperature controller is configured with different temperature settings, each corresponding to a number of said cooling fans, and controls said fan-driving circuits to activate a number of said cooling fans according to the temperature setting corresponding to a temperature detected by said at least one temperature sensor.

2. A cooling system for a computer power supply unit, comprising:
a housing;
a plurality of cooling fans mounted in said housing;
a temperature controller mounted in said housing;
a plurality of temperature sensors mounted in said housing and coupled electrically to said temperature controller; and
a plurality of fan-driving circuits coupled electrically and respectively to said cooling fans and controlled by said temperature controller for activating and deactivating said cooling fans, respectively;
wherein said temperature controller controls each of said fan-driving circuits to activate the respective one of said cooling fans according to a temperature detected by a corresponding one of said temperature sensors.
